(19) United States
(12) Patent Application Publication
(10) Pub. No.: US 2010/0233868 A1
(43) Pub. Date: Sep. 16, 2010

(54) Adhesive Sheet and a Processing Method of Semiconductor Wafer, and a Manufacturing Method of Semiconductive Chip

(76) Inventors: Jun Maeda, Munchen (DE); Keiko Tanaka, Tatebayashi-shi (JP)

Correspondence Address: CAHN & SAMUELS LLP, 1100 17th STREET NW, SUITE 401, WASHINGTON, DC, 20036, US

(21) Appl. No.: 12/724,459

(22) Filed: Mar. 16, 2010

(30) Foreign Application Priority Data
Mar. 16, 2009 (JP) 2009-063264

(51) Int. Cl. H01L 21/78; C09J 7/02

(52) U.S. Cl. 438/464; 428/354; 257/E21.599

(57) ABSTRACT

The objective of the present invention is to solve the various problems involving the evaporation or the moving of the low-molecular weight included in the intermediate layer, in the adhesive sheet having a multilayered adhesive layer. The above mentioned problems are solved by an adhesive sheet comprising a substrate, an intermediate layer formed thereon, and an adhesive layer formed on said intermediate layer, wherein, said intermediate layer includes an energy ray-curable polymer in which an energy ray-polymerizable group and a radical-generating group initiating a polymerization under excitation by an energy ray are bound at a main chain or side chain.

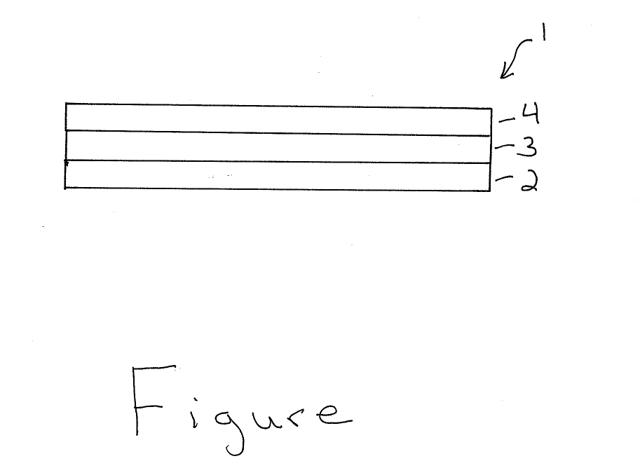

### TECHNICAL FIELD

The present invention relates to an adhesive sheet, further specifically, the present invention relates to the adhesive sheet suitably used for protecting the surface by sticking to a front surface when processing a back side of an adherend having a significant roughness formed on the front surface. Particularly, the present invention relates to the adhesive sheet used as a wafer processing adhesive sheet to protect a circuit surface when grinding the back side of a semiconductor wafer; and the use of said adhesive sheet.

### BACKGROUND ART

Along with a high density packaging of a semiconductor device, a projections (also called as bumps) formed by the spherical solder is used for bonding an IC chip and a substrate. Particularly, when the IC chip is directly bonded, the bumps having a diameter of several hundreds μm or so are used in many cases. Such bumps are bonded in advance to the circuit face of the semiconductor wafer in high density.

On the other hand, along with the wide spreading of the IC card, the IC chip is demanded to be thinner. Thus, it is demanded to make the thickness of the wafer as thin as 50 to 100 μm or less by grinding the back side of the wafer. Since the wafer is a fragile member, the chance of breaking it during the processing or the transportation increases as the wafer becomes thinner. Also, the circuit face may be damaged or contaminated by the sawdust produced during the back side grinding. Therefore, when grinding the wafer extremely thin, or when transporting the extremely thin wafer, the circuit surface side of the wafer is protected by a surface protection sheet such as an adhesive sheet or so to proceed the work.

However, when the back side of the wafer formed with above described bumps on the circuit surface is ground, the difference in the pressure due to the height difference of the bumps directly influences the back side of the wafer, and produces so called dimples which are dents or cracks. As a result, the semiconductor device is damaged. Therefore, the adhesive layer of the surface protection sheet is thickened, and by increasing the fluidity of the adhesive, the adhesive layer and the wafer are closely contacted. Thereby the difference in the pressure due to the height difference of the bumps is solved by the cushion property of the adhesive layer. However, if the adhesive layer is thickened and the fluidity thereof is increased, the adhesive easily gets into the bottom portion of the bumps. Therefore, the adhesive stuck to the bottom portion of the bumps causes breakage within the layer by the releasing procedure of the surface protection sheet, and the portion thereof may remain at the circuit surface. This was a problem which could happen even when the surface protection sheet using energy ray-curable adhesive sheet was used. If the adhesive that remained on the circuit surface were not removed by solvent cleaning or so, it remains as a contaminant of the device, and compromise the reliability of the finished device.

Also, as the IC card has been widely spread, it is demanded to become further thinner. Thus, the semiconductor chip which conventionally had a thickness of 350 μm or so is in demand to have a thickness of as thin as 50 to 100 μm or less.

As a method to achieve such a thin chip, JP A H05-335411 (Patent document 1) discloses a production method of the semiconductor chip which forms the groove having a predetermined depth from the surface side of the wafer and then grinds from the back side thereof. Such process is also called as Dicing Before Grinding (DBG) process. When the back side of the wafer is ground, in order to protect the circuit on the wafer surface and to fix the wafer (chip), the surface protection sheet is stuck on the wafer surface formed with the groove.

In such DBG process, when the bumps are formed on the circuit face of the semiconductor chip, addition to the problems caused by the back side grinding due to the usual method described in the above, there is other problem. In the DBG process, the wafer is divided into chips on the surface protection sheet at the final step of grinding. When the bumps are present on the circuit surface, it is difficult to completely stick the surrounding area of each chips; hence the grinding water flows in from the space between each chips and may contaminate the circuit surface.

Thus, the surface protection sheet used in the DBG process is demanded to have further following property to the face formed with the bumps compared with that of the usual back side grinding.

In order to correspond to the advanced demand for such adhesive sheet, the adhesive layer of the adhesive sheet for the wafer processing may be made into a multilayer, aiming to provide various additional functions to the adhesive layer. For example, JP A 2002-212530 (patent document 2) proposes the surface protection sheet formed by stacking a substrate, an intermediate layer having a predetermined elastic modulus, and the adhesive layer having a predetermined elastic modulus. This patent document 2 discloses that a film having a high stress relaxation rate can be used as the substrate. Also, JP A 2004-331743 (Patent document 3) discloses the adhesive sheet comprising the substrate, the intermediate layer formed thereon, and the adhesive layer formed on said intermediate layer, wherein said intermediate layer is formed by solventless resin, and consisting of a film having 60% or more of the stress relaxation rate after 10 seconds of applying 20% torsional stress. By using such substrate and intermediate layer having high stress relaxation rate, the remaining stress declines rapidly, hence the above mentioned problems caused by the difference in the pressure due to the high bumps having a significant roughness on the surface can be solved. Also, since the intermediate layer and the adhesive layer has the predetermined elastic modulus, even for the high bump wafer having a significant roughness on the surface, the surface protection function can be sufficiently achieved.

The adhesive layer in the patent document 2 and 3 are described that it can be the energy ray-curable adhesive. Also, as the material of the intermediate layer of the patent document 2 and 3, the energy ray-curable resin is described. As for these energy ray-curable adhesive or resin, a photopolymerization initiator and an energy ray-curable resin having low-molecular weight is included.

The usual energy ray-curable adhesive layer is obtained by diluting, an adhesive polymer, the photopolymerization initiator and the energy ray-curable resin by a solvent, and coating over the substrate or releasing paper, followed by drying. Similarly, the intermediate layer is obtained by coating the liquid composition including various low-molecular weight compounds, and drying. However, when the low-molecular weight compounds is included within the energy ray-curable adhesive or the intermediate layer, the low-molecular weight compounds evaporates when drying, thus in some cases the adhesive layer or the intermediate layer having a designed composition couldn't be obtained.

Also, when the intermediate layer is provided in addition to the energy ray-curable adhesive layer, in order to provide various additional functions to the adhesive layer as of the patent documents 2 and 3, since the low-molecular weight compounds included in the energy ray-curable adhesive and the intermediate layer migrate each other, the physical property of the adhesive layer and the intermediate layer changes with time, hence in some cases, the property at designing the material were not able to be obtained.

Furthermore, when the wafer is processed using the adhesive sheet for wafer processing, the semiconductor wafer may be heated or the process involving the heat generation such as a dry etching may be performed. During such moment, the low-molecular weight compounds evaporates and the physical property of the adhesive layer and the intermediate layer may change. Also, when grinding the back side of the wafer, the water is sprayed in order to remove the generated heat or the dust; however, the low-molecular weight compound may be washed away by the water.

Furthermore, after completing the predetermined processing treatment, even if the adhesive layer is cured and the wafer processing adhesive sheet is released, the problems that the low-molecular weight compounds moves to the adherend and contaminate the wafer or the chip are happened.

### SUMMARY OF THE INVENTION

### Technical Problems to be Solved by the Invention

Therefore, the objective of the present invention is to solve the various problems involving the evaporation or the moving of the low-molecular weight included in the intermediate layer, in the adhesive sheet having a multilayered adhesive layer.

### BRIEF DESCRIPTION OF THE DRAWING

The sole FIGURE is a schematic diagram of an adhesive sheet according to an embodiment of the invention.

### MEANS FOR SOLVING THE TECHNICAL PROBLEMS

The subjects of the present invention aiming to solve such problems are as follows.

(1) An adhesive sheet 1 comprising a substrate 2, an intermediate layer 3 formed thereon, and an adhesive layer 4 formed on said intermediate layer, wherein, said intermediate layer includes an energy ray-curable polymer in which an energy ray-polymerizable group and a radical-generating group initiating a polymerization under excitation by an energy ray are bound at a main chain or side chain.

(2) The adhesive sheet as set forth in (1), wherein said radical-generating group includes phenyl carbonyl group which may comprise a substituent group at an aromatic ring.

(3) The adhesive sheet as set forth in (1) or (2), wherein said radical-generating group is derived from a monomer obtained by adding a compound containing a polymerizable double bond to a hydroxyl group of a photopolymerization initiator having the hydroxyl group.

(4) The adhesive sheet as set forth in any one of (1) to (3); wherein said energy ray-curable polymer have weight average molecular weight of 300000 to 1600000.

(5) The adhesive sheet as set forth in any one of (1) to (4) used for processing of a semiconductor wafer.

(6) A processing method of a semiconductor wafer, wherein a circuit surface of the semiconductor wafer formed with a circuit on the surface is stuck to the adhesive layer of the adhesive sheet as set forth in any one of (1) to (5), and performs a back side processing of said semiconductor wafer.

(7) The processing method of the semiconductor wafer as set forth in (6), wherein said back side processing of said semiconductor wafer is a back side grinding.

(8) A processing method of the semiconductor wafer, wherein a circuit surface of the semiconductor wafer formed with a circuit on the surface is stuck to the adhesive layer of the adhesive sheet as set forth in any one of (1) to (5), and performing a dicing of said semiconductor wafer.

(9) The processing method of the semiconductor wafer as set forth in any one of (6) to (8), wherein the circuit surface of the semiconductor wafer formed with the circuit having bumps on the surface is stuck to the adhesive layer of the adhesive sheet, and performs a processing of said semiconductor wafer.

(10) A processing method of the semiconductor wafer including the steps of forming the grooves having a depth of cut shallower than a wafer thickness from the surface of the semiconductor wafer formed with the circuit having bumps, sticking the adhesive sheet as set forth in any one of (1) to (5) on to the circuit surface, then thinning the wafer thickness by back side grinding of said semiconductor wafer, and dividing into individual chips, followed by picking up said chips.

### EFFECTS OF THE INVENTION

According to the present invention, in the adhesive sheet having a multilayered adhesive layer, the low-molecular weight compounds included in the intermediate layer is significantly reduced; hence various problems can be solved such as compositional changes due to the low-molecular weight compounds moving and evaporating, and volatile gas generation or so. Further, when using as the processing of the semiconductor wafer, the water is sprayed in order to remove the sawdust or the generated heat during back side grinding or dicing the wafer; however, the compositional changes of the adhesive layer due to the loss of the low-molecular weight compounds does not occur since the low-molecular weight compounds included in the adhesive layer is significantly reduced.

### BEST MODE FOR CARRYING OUT THE INVENTION

Hereinafter preferable embodiment of the present invention will be described including the best mode of the invention.

### (The Adhesive Sheet)

An adhesive sheet of the present invention comprises a substrate, and a multilayered adhesive sheet. Specifically, the multilayered adhesive layer comprises an outer most adhesive layer (hereinafter refer to as “adhesive layer”) to hold the wafer at the outer most layer, and an intermediate layer present between the substrate and the outer most adhesive layer. Also, if needed, a releasing film may be used to protect the adhesive layer.

### (The Intermediate Layer)

The intermediate layer of the present invention comprises an energy ray-curable polymer (A), and additives (B) if needed.

### (The Energy Ray-Curable Polymers (A))

The energy ray-curable polymers (A) is obtained by reacting a functional group derived from a functional group containing monomer of a radical-generating group containing polymer (a1) to the energy ray-polymerizable group containing compound (a2).

(The Radical-Generating Group Containing Polymer (a1))

The radical-generating group containing polymer (a1) is formed by polymerizing the radical-generating group containing monomer (a1-1), the functional group containing monomer (a1-2) for introducing the energy ray-polymerizable group, and other monomers (a1-3) if needed.

(The Radical-Generating Group Containing Monomer (a1-1))

The radical-generating group containing monomer (a1-1) used in the present invention comprises a polymerizable double bond, and a group generating a free radical which initiate the polymerization reaction under the excitation by the energy ray (a radical-generating group). As for the radical-generating group, for example, a group including a phenylcarbonyl group which can have a substituent group on an aromatic ring as shown in the following general chemical formula may be mentioned.

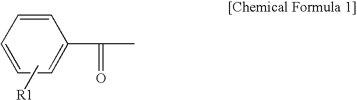

(R₁ is hydrogen or a hydrocarbon group having 1 to 12 of carbon atoms; and an ether bond and hydroxyl group may be comprised in R₁.)

Such radical-generating group containing monomer is obtained by addition reaction of, for example, the compound comprising the radical-generating group and the compound comprising the polymerizable double bond.

As for the compound comprising the radical-generating group, for example, a photopolymerization initiator comprising the hydroxyl group may be mentioned. Specifically,

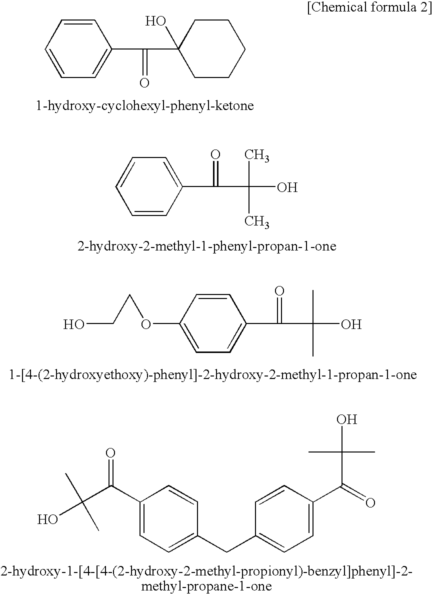

may be mentioned.

The monomer obtained by addition reaction of such compound comprising the radical-generating group and the compound comprising the polymerizable double bond is preferably as the radical-generating group containing monomer (a1-1).

As for the compound comprising the polymerizable double bond, the compound comprising the polymerizable double bond comprising the functional group reacting with the hydroxyl group is preferable, and for example, methacryloyloxyethyl isocyanate, meth-isopropenyl-α, α-dimethylbenzyl isocyanate, methacryloyl isocyanate, allyl isocyanate; glycidyl (meth)acrylate and; (meth)acrylic acid may be mentioned. Also, acryloyl monoisocyanate compounds each obtained by reacting a diisocyanate or polyisocyanate compound with hydroxyethyl (meth)acrylate; and acryloyl monoisocyanate compounds each obtained by reaction of diisocyanate or polyisocyanate compound, a polyol compounds and hydroxyethyl (meth)acrylate.

By reacting said compound comprising the hydroxyl group and the radical-generating group, with said compound comprising the polymerizable double bond (for example, methacryloyloxyethyl isocyanate); the hydroxyl group of the compound comprising the radical-generating group and the functional group (for example, isocyanate group) of the compound comprising the polymerizable double bond reacts; thereby the radical-generating group containing monomer (a1-1) having the polymerizable double bond can be obtained.

As for the specific example of other radical-generating group containing monomers (a1-1), o-acryloylbenzophenone, p-acryloylbenzophenone, o-methacryloylbenzophenone, p-methacryloylbenzophenone, p-(meth)acryloylethoxybenzophenone, monohydroxyalkylacrylate having 2 to 12 methylene group derived from the benzophenone carbonic acid shown in the following general formula, or bezophenone carbonate ester of the methacryloylmonohydroxyanilide,

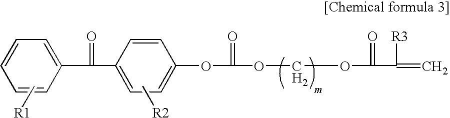

(R₁ and R₂ may be hydrogen atom or alkyl group having 1 to 4 of carbon atoms respectively, R₃ may be hydrogen or a methyl group and m is an integer from 2 to 12), and compound in the following general formula,

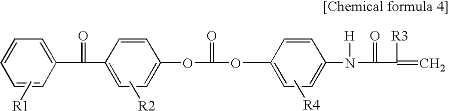

(R₁ and R₂ may be hydrogen atom or alkyl group having 1 to 4 of carbon atoms respectively, and R₃ and R₄ may be hydrogen or methyl group respectively.) may be mentioned.
(The Functional Group Containing Monomer (a1-2))

The functional group containing monomer (a1-2) constituting the radical-generating group containing polymer (a1) is a monomer to introduce the energy ray-polymerizable group to the energy ray-curable polymer of the present invention. It is a monomer comprising the polymerizable double bond, and the functional group, as the hydroxyl group, the carboxyl group, the amino group, the substituted amino group, the epoxy group or so in the molecule, and preferably an unsaturated compound containing the hydroxyl group or an unsaturated compound containing the carboxyl group are used.

As specific examples of such functional group containing monomer (a1-2), an acrylate containing hydroxyl group such as 2-hydroxyethyl acrylate, 2-hydroxyethyl methacrylate, 2-hydroxypropyl acrylate, 2-hydroxypropyl methacrylate, 2-hydroxybutyl acrylate and 2-hydroxybutyl acrylate; and compounds containing carboxyl group such as acrylic acid, methacrylic acid, and itaconic acid or so, may be mentioned. The above mentioned functional group containing monomer may be used alone or in combination of two or more thereof.

(Other Monomers (a1-3))

Other monomers (a1-3) constituting the radical-generating group containing polymer (a1) are not particularly limited, however, for example, acrylic monomer, or olefin monomer may be mentioned.

As for the acrylic monomer, an (meth) acrylic acid alkyl ester having 1 to 18 carbon atoms of alkyl group is used. As the derivative of (meth) acrylic acid alkyl ester, methyl acrylate, methyl methacrylate, ethyl acrylate, ethyl methacrylate, propyl acrylate, propyl methacrylate, isopropyl acrylate, isopropyl methacrylate, n-butyl acrylate, n-butyl methacrylate, isobutyl acrylate, isobutyl methacrylate, n-hexyl methacrylate, 2-ethyl hexyl acrylate, 2-ethylhexyl methacrylate, cyclohexyl acrylate, lauryl methacrylate or so may be mentioned.

Furthermore, a vinyl monomer copolymerizable with the above mentioned acrylic monomers may be copolymerized. As for the copolymerizable vinyl monomer, styrene, α-methyl styrene, vinyl toluene, vinyl formate, vinyl acetate, acrylonitrile, glycidyl acrylate, glycidyl methacrylate, dimethylacrylamide or so may be mentioned.

(The Formation of the Radical-Generating Group Containing Polymer (a1))

The radical-generating group containing polymer (a1) is formed from the above mentioned radical-generating group containing monomer (a1-1), the functional group containing monomer (a1-2), and other monomers (a1-3) if need.

The radical-generating group containing polymer (a1) contains the structural units derived from above radical-generating group containing monomer (a1-1) usually in an ratio of 0.1 to 30 weight %, preferably 0.5 to 10 weight %, and more preferably 1 to 5 weight %. The radical-generating group containing polymer (a1) contains the structural units derived from above functional group containing monomer (a1-2) usually in an ratio of 1 to 70 weight %, preferably 5 to 40 weight %, and more preferably 10 to 30 weight %. The radical-generating group containing polymer (a1) contains the structural units derived from above other monomers (a1-3) usually in an ratio of 0 to 99 weight %, preferably 35 to 90 weight %, and more preferably 50 to 80 weight %.

The radical-generating group containing polymer (a1) is obtained by copolymerizing the above mentioned radical-generating group containing monomer (a1-1), the functional group containing monomer (a1-2), and other monomers (a1-3) by a usual method; however, the production method of the radical-generating group containing polymer (a1) is not particularly limited, and for example, it may be produced by using the solution polymerization under the presence of the solvent, the chain transfer agent, and the polymerization initiator or so; or by the aqueous emulsion polymerization under the presence of the emulsifier, the chain transfer agent, the polymerization initiator, and the dispersing agent, or so.

Note that, the monomer concentration during the polymerization is usually 30 to 70 weight %, preferably 40 to 60 weight % or so. As for the polymerization initiator used for the polymerization, a persulfate such as potassium persulfate, ammonium persulfate or so, an azo compound such as 2,2-′azobisisobutylonitrile, 2,2′-azobis(2,4-dimethylvaleronitrile) or so, an peroxide such as hydrogen peroxide, benzoyl peroxide, lauryl peroxide or so, and a redox polymerization initiator comprising the combination of ammonium persulfate, with sodium sulfite or acid sodium sulfite or so may be mentioned. The amount of the polymerization initiator mentioned in the above is controlled within the range of 0.2 to 2 weight %, and preferably within the range of 0.3 to 1 weight % with respect to the whole amount of the monomer used in the polymerization.

Further, as for the chain transfer agent during the polymerization; alkyl mercaptans such as octyl mercaptan, nonyl mercaptan, decyl mercaptan, dodecyl mercaptan or so; thioglycolates such as octyl thioglycolate, nonyl thioglycolate, 2-ethyl hexyl thioglycolate, 2-ethyl hexyl β-mercaptopropionate or so; 2,4-diphenyl-4-methyl-1-pentene, 1-methyl-4-isopropylidine-1-cyclohexene or so may be mentioned. Particularly, when using the thioglycolates, 2,4-diphenyl-4-methyl-1-pentene, and 1-methyl-4-isopropylidine-1-cyclohexene, it is preferable since the obtained copolymer has low odor. Note that, the amount of chain transfer agent is controlled within the range of 0.001 to 3 weight % or so with respect to the whole monomer to be polymerized. Also, usually, the polymerization reaction is performed under 60 to 100° C. for 2 to 8 hours. Further, a viscosity improver, a wetting agent, a leveling agent, and an anti-foaming agent may be added accordingly.

(The Energy Ray-Polymerizable Group Containing Compound (a2))

The energy ray-polymerizable group containing compound (a2) includes, the substituent group which can react with the functional group in the radical-generating group containing polymer (a1), that is the functional group derived from the above mentioned functional group containing monomer (a1-2). This substituent group varies depending on the type of said functional group. For example, when the functional group is a hydroxyl, the substituent group is preferably an isocyanate or epoxy group. When the functional group is a carboxyl group, then the substituent group is preferably an isocyanate or epoxy group. When the functional group is an amino or a substituted amino group, the substituent group is preferably an isocyanate or the like. When the functional group is epoxy group, the substituent group is preferred to be a carboxyl group. One substituent group is contained in every molecule of the energy ray-polymerizable group containing compound (a2).

Further, 1 to 5, and preferably 1 to 2 carbon-carbon double bond of the energy ray-polymerizable group, is contained in every molecule of the energy ray-polymerizable group containing compound (a2). As specific examples of the energy ray-polymerizable group containing compound (a2); methacryloyloxyethyl isocyanate, meth-isopropenyl-α, α-dimethylbenzyl isocianate, methacryloyl isocyanate, allyl isocyanate, glycidyl (meth) acrylate and (meth) acrylic acid or so may be mentioned. Also, acryloyl monoisocyanate compounds each obtained by reaction of a diisocyanate or polyisocyanate compound with hydroxyethyl (meth) acrylate; acryloyl monoisocyanate compounds each obtained by reaction of a mixture of a diisocyanate or polyisocyanate compound, a polyol compound and hydroxyethyl (meth) acrylate may be mentioned as well.

As for the energy ray-polymerizable group containing compound (a2), an energy ray-polymerizable group containing polyalkyleneoxy compound, as described in the following, can be used as well.

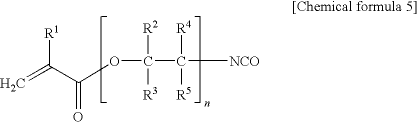

In the above formula, R¹ is hydrogen atom or methyl group, and preferably methyl group. R² to R⁵ are each independently hydrogen or alkyl group having 1 to 4 carbon atoms, and preferably hydrogen. Further, n is a integer number of 2 or higher, and preferably 2 to 4. That is, since n is 2 or higher, in the above energy ray-polymerizable group containing polyalkyleneoxy compound includes 2 or more R². In here, R² which exists 2 or more, may be same or different from each other. This can be said to R³ to R⁵ as well. NCO in the chemical formula 5 indicates isocyanate group.

### (Formation of the Energy Ray-Curable Polymer (A))

The energy ray-curable polymer (A) of the present invention is obtained by reacting the radical-generating group containing polymer (a1) and the energy ray-polymerizable group containing compound (a2) having a substituent group which reacts with the functional group of said radical-generating group containing polymer (a1). Hereinafter, the production method of the energy ray-curable polymer (A) of the present invention will be described, particularly the example of using the acrylic copolymer as a main skelton will be described. However, the energy ray-curable polymer (A) of the present invention is not limited to those obtained by the method of production described hereinafter.

When manufacturing the energy ray-curable polymer (A), the energy ray-polymerizable group containing compound (a2) is used in an amount of 100 to 20 equivalent amounts, preferably 95 to 40 equivalent amounts, and more preferably 90 to 60 equivalent amounts, per 100 equivalent amounts of the functional group containing monomer (a1-2) of the radical-generating group containing polymer (a1).

The reaction between the radical-generating group containing polymer (a1) and the energy ray-polymerizable group containing compound (a2) is usually performed at room temperature and at atmospheric pressure for 24 hours. It is preferable that this reaction is carried out in a solution, for example, an ethyl acetate solution in the presence of a catalyst such as dibutyltin laurate.

As a result, the functional group present in the side chain of the radical-generating group containing polymer (a1) and the substituent group in the energy ray-polymerizable group containing compound (a2) reacts, and the energy ray-polymerizable group is introduced into the compound containing the radical-generating group (a1); thereby the acrylic energy ray-curable polymer (A) is obtained. In this reaction the reactivity between the functional group and the substituent group is usually 70% or more, preferably 80% or more, and it is preferable that the non reacting substituent group remains in the energy ray-curable polymer (A).

The weight average molecular weight of the energy ray-curable polymer (A) bonded with the energy ray-polymerizable group and the radical-generating group is preferably 300,000 to 1,600,000, and further preferably 400,000 to 900,000. Also, usually 1×10²¹ to 1×10²⁴, preferably 5×10²¹ to 8×10²³, and more preferably 1×10²² to 5×10²³ of polymerizable groups are contained per 100 g of the energy ray-curable polymer (A). Further, usually 1×10²⁰ to 1×10²⁴, preferably 2×10²⁰ to 5×10²³, and more preferably 5×10²⁰ to 2×10²³ of the radical-generating groups are contained per 100 g of the energy ray-curable polymer (A).

### (Other Additives (B))

By mixing suitable other additives (B), depending on the needs, to the above mentioned energy ray-curable polymer (A), the intermediate layer of the energy ray-curable type can be obtained. For example, as other additives (B), a crosslinkers, a tackifier, a pigment, a colorant, and a filler may be mentioned; however, the intermediate layer may be formed without mixing thereof and only by the energy ray-curable polymer (A).

As for the crosslinkers, for example, an organic polyvalent isocyanate compound, an organic polyvalent epoxy compound and an organic polyvalent imine compound or so may be mentioned.

As for the above mentioned organic polyvalent isocyanate compound, an aromatic polyvalent isocyanate compound, an aliphatic polyvalent isocyanate, and an alicyclic polyvalent isocyanate compound may be mentioned. As for further specific examples of the organic polyvalent isocyanate compound; 2,4-tolylene diisocyanate, 2,6-tolylene diisocyanate, 1,3-xylylene diisocyanate, 1,4-xylylene diisocyanate, diphenylmethane-4,4′-diisocyanate, diphenylmethane-2,4′-diisocyanate, 3-methyldiphenylmethane diisocyanate, hexamethylene diisocyanate, isophorone diisocyanate, dicyclohexylmethane-4,4′-diisocyanate, dicyclohexylmethane-2,4′-diisocyanate, and lysine isocyanate or so may be mentioned. A trimer of each of these polyvalent isocyanate compounds or an isocyanate terminated urethane prepolymer obtained by reacting each of these polyvalent isocyanate compounds with a polyol compound may be used as well.

As for specific examples of the above organic polyvalent epoxy compound, for example, a bisphenol A epoxy compound, a bisphenol F epoxy compound, 1,3-bis(N,N-diglycidylaminomethyl) benzene, 1,3-bis(N,N-diglycidylaminomethyl) toluene, N,N,N′N-tetraglycidyl-4,4-diaminodiphenylmethane or so may be mentioned.

As specific examples of the above organic polyvalent imine compound, a N,N′-diphenylmethane-4,4′-bis(1-azridinecarboxyamide), trimethylolpropane-tri-β-aziridinyl propionate, tetramethylolmethane-tri-β-aziridinyl propionate N,N′-toluene-2,4-bis(1-aziridinecarboxyamindo)triethylenemelamine or so may be mentioned.

The used amount of the above mentioned crosslinkers is preferably 0.01 to 20 parts by weight, and more preferably 0.1 to 10 parts by weight or so with respect to 100 parts by weight of the energy ray-curable polymer (A).

As the tackifier, for example, a rosin resin, a terpene phenol resin, a terpene resin, an aromatic hydrocarbon modified terpene resin, a petroleum resin or so, a coumarone indene resin, a styrene resin, a phenol resin, and a xylene resin may be mentioned.

As the pigment, for example, an inorganic pigment such as a titanium oxide, a ferric oxide, an ultramarine blue, an iron blue, a carbon black, a cobalt blue, and a chrome yellow; and an organic pigment such as a insoluble azo pigment of an anilide, an acetoacetanilide bisazo, and a pyrazolones; a copper phthalocyanine blue, a quinacridone, a thioindigo, and a indusron or so may be mentioned.

As for the coloring, for example, an azo coloring, a quinoline coloring, an anthraquinone coloring, an indigo coloring, a cyanine coloring, a naphthoquinone coloring, a phthalocyanine coloring, nitro coloring, and a metal complexed coloring or so may be mentioned.

As the filler, a known inorganic filler such as a synthetic silica, a titanium oxide, an aluminum hydroxide, and a calcium carbonate; or known organic filler may be mentioned.

The content of the tackifier, the pigment, the coloring, and the filler or so may be included within the range which does not interfere the objectives of the present invention; however, it is preferable to comprise in the ratio of 3 parts by weight or less with respect to 100 parts by weight of the energy ray-curable polymer (A), especially when it is a low-molecular weight compounds having molecular weight of 1000 or less,

### (The Characteristics of the Intermidiate Layer)

In the intermediate layer of the energy ray-curable polymer manufactured as such, the energy ray-curable polymer (A) by itself has a function as the photopolymerization initiator, and a function as the energy ray-polymerizable compound. Hence there is no need to further add the low-molecular weight compounds such as the photopolymerization initiator or the energy ray-polymerizable compound to the energy ray-curable compound (A). Thus, according to the energy ray-curable intermediate layer of the present invention, the contents of the low-molecular weight compounds in the intermediate layer are significantly reduced, and thereby the physical property change occurred by the move of the low-molecular weight compounds to the adhesive layer, and the compositional changes occurred by the evaporation, and the volatile gas generation or so of problems can be solved.

A storage elastic modulus of the intermediate layer at 23° C. before energy ray-curing is preferably less than the elastic modulus of the adhesive layer at 23° C. which is described in the following, and more preferably 1 to 100% of the storage elastic modulus of the adhesive layer described in the following, further preferably 10 to 90%, and particularly preferably within the range between 30 to 80%.

Since the intermediate layer is an energy ray-curable polymer, it has properties that polymerize and cures by applying the energy ray and increases the storage elastic modulus.

As for the energy ray, specifically, an ultraviolet ray, and an electronic ray or so may be used. Also, the irradiation amount varies depending on the type of the energy ray, and for example, when using the ultraviolet ray, the ultraviolet ray intensity is preferably 50 to 300 mW/cm² or so, and the ultraviolet ray irradiation amount is preferably 100 to 1200 mJ/cm² or so.

The thickness of the intermediate layer is preferably within the range of 50 to 600 μm, more preferably 100 to 500 μm, and particularly preferably 150 to 400 μm. If the intermediate layer is too thin, then the adhesive sheet cannot follow the roughness of the surface of the bumps or so, and thus the roughness cannot be resolved. Also, if the intermediate layer is too thick, while at the rolled status, a problem such as the intermediate layer being squeezed out from the edge portion of the roll due to the roll pressure or so may happen.

The intermediate layer has elastic modulus which can sufficiently follow the roughness of the bumps or so, before the energy ray irradiation. Thus, the intermediate layer is embedded into the wafer surface where the bumps are formed on, thereby the roughness is resolved and the wafer can be maintained in a flat status. Further, by polymerizing and curing due to the energy ray irradiation, the wafer can be fixed at said flat status. Therefore, even if strong shear force is applied on to the wafer during the wafer back side grinding, the vibration and the positional shift of the wafer can be prevented, thus the wafer can be stably maintained in the flat status and can be ground till ultrathin.

### (The Substrate)

The substrate used in the adhesive sheet of the present invention is not particularly limited, and a polyethylene film, a polypropylene film, a polybutene film, a polybutadiene film, a polymethylpentene film, a polyvinyl chloride film, a vinyl chloride copolymer, a polyethylene terephthalate film, a polybutylene terephthalate film, a polyurethane film, an ethylene/vinyl acetate film, an ionomer resin film, an ethylene/(meth)acrylic acid copolymer film, an ethylene/(meth) acrylic acid ester copolymer film, a polystyrene film, a polycarbonate film, a fluoro resin film, a low density polyethylene (LDPE) film, a linear low density polyethylene (LLDPE) film, or hydrogenated and modified film thereof may be used. Also, the crosslinking film thereof may be used as well. The above mentioned substrate may be alone, or it may be a composite film combining two or more thereof.

The thickness of the substrate may vary depending on the use, however, usually it is 10 to 1000 μm, preferably 30 to 500 μm, and more preferably 50 to 300 μm.

For example as described hereinafter, when the ultraviolet ray is used as the energy ray applied to cure the adhesive, among the above mentioned substrates, the one which is transparent to the ultraviolet ray is preferable. Also, when the electron beam is used as the energy ray, the substrates do not have to be transparent; hence addition to the films mentioned in the above, the opaque film by coloring them may be used.

### (The Adhesive Layer)

The adhesive layer is conventionally obtained by formed from various known pressure-sensitive adhesives. Such adhesives are not particularly limited, however for example, an acrylic, a rubber, a silicone, an urethane, a polyester, and a polyvinyl ether adhesive or so may be used. Also, the adhesive of an energy curable type, a heat foaming type, and a water swellable type may be used.

When using as the adhesive of the present invention, various acrylic copolymers which can easily control adhesive strength is preferably used. As for the acrylic monomer constituting the acrylic copolymer, an alkyl ester (meth) acrylate having 1 to 18 carbon atoms of alkyl group is used. As alkyl ester (meth) acrylate; methyl acrylate, methyl methacrylate, ethyl acrylate, ethyl methacrylate, propyl acrylate, propyl methacrylate, isopropyl acrylate, isopropyl methacrylate, n-butyl acrylate, n-butyl methacrylate, isobutyl acrylate, isobutyl methacrylate, n-hexyl methacrylate, 2-ethyl hexyl acrylate, 2-ethylhexyl methacrylate, cyclohexyl acrylate, lauryl methacrylate or so may be mentioned.

Also, the functional group containing monomer which can copolymerize with the above mentioned acrylic monomer may be copolymerized. As for the example of copolymerizable functional group containing monomer; for example, monomer having the hydroxyl group, the carboxyl group, the amino group, the substituted amino group, and the epoxy group or so in its molecule may be mentioned. Preferably, the hydroxyl group containing unsaturated compound or a carboxyl group containing unsaturated compound is used. As further specific examples of such functional group containing monomer; an acrylate containing hydroxyl group such as 2-hydroxyethyl acrylate, 2-hydroxyethyl methacrylate, 2-hydroxypropyl acrylate, 2-hydroxypropyl methacrylate, 2-hydroxybutyl acrylate and 2-hydroxybutyl methacrylate; and compounds containing carboxyl group such as acrylic acid, methacrylic acid, and itaconic acid or so, may be mentioned. The above mentioned functional group containing monomer may be used alone or in combination of two or more thereof.

Furthermore, a vinyl monomer copolymerizable with the above mentioned acrylic monomer may be copolymerized. As for the copolymerizable vinyl monomer, styrene, α-methyl styrene, vinyl toluene, vinyl formate, vinyl acetate, acrylionitrile, glycidyl acrylate, glycidyl methacrylate, dimethylacrylamide or so may be mentioned.

Also, suitable additives may be mixed into the adhesive depending on the needs. As the additives, for example, the same crosslinkers, tackifier, pigment, coloring, and filler as those used in the intermediate layer may be used. However, the adhesive composition may only be said polymers without mixing additives.

Also the physical property thereof is not particularly limited. However, the storage elastic modulus at 23° C. is preferably within the range of 5.0×10⁴ to 1.0×10⁷ Pa, more preferably 6.0×10⁴ to 5.0×10⁶ Pa, and particularly preferably 8.0×10⁴ to 1.0×10⁶ Pa. Note that, when forming the adhesive layer by the energy ray-curable adhesive, the above mentioned storage elastic modulus are that of the adhesive layer before the energy ray irradiation.

When the storage elastic modulus of the adhesive layer at 23° C. is lower than 5.0×10⁴ Pa, then the adhesive layer tends to squeeze out from the edge portion of the adhesive sheet and become easily shear deformed by the grinding force due to the lack of the cohesion force. Thus the thickness of the wafer after the grinding greatly varies. Also, if the shear force is applied to the adhesive embedded into the dents of the bumps, the adhesive likely remains in the wafer surface. On the other hand, when the storage elastic modulus of the adhesive layer at 23° C. is higher than 1.0×10⁷ Pa, then the adhesive layer is hardened, and becomes difficult to follow the roughness of the bumps; thereby tends to easily cause problems such as varying the thickness of the wafer after the grinding, or allowing the cooling water of the grinding process to leak in from the space between the bumps and the adhesive sheet.

If the storage modulus at 23° C. of the adhesive layer and the intermediate layer satisfy said relationship, the sticking thereof while sufficiently following the roughness of the bumps becomes possible, and also the shear force against the adhesive layer is dispersed, thus the adhesives becomes difficult to remain during the releasing. Also, it can be stuck so that the difference of the thickness between the portion where the bumps are concentrated and the parts where the bumps are scarce can be cancelled.

The thickness of the adhesive layer varies depending on the use, however, usually it is 5 to 100 μm, preferably 10 to 80 μm, and further preferably 20 to 60 μm or so. When the adhesive layer becomes thin, then the ahesivenss or the surface protective function may be lowered.

### (The Releasing Film)

As the releasing film, various films having the surface of releasing property are used. As specific examples of such releasing film, a polyethylene film, a polypropylene film, a polybutene film, a polybutadiene film, a polymethylpentene film, a polyvinyl chloride film, a vinyl chloride copolymer film, a polyethylene terephthalate film, a polybutylene terephthalate film, a polyurethane film, an ethylene/vinyl acetate film, an ionomer resin film, an ethylene/(meth)acrylic acid copolymer film, an ethylene/(meth) acrylic acid ester copolymer film, a polystyrene film, a polycarbonate film, a fluorocarbon resin film, a low density polyethylene (LDPE) film, a linear low density polyethylene (LLDPE) film, and hydrogenated and modified film thereof may be used. Also, the crosslinking film thereof may be used as well. The above mentioned film may be alone, or it may be a composite film combining two or more thereof.

As the releasing film, the film in which the releasing treatment is performed on to the one of the surface of above mentioned film is preferable. The releasing agent used for the releasing treatment is not particularly limited; however, a silicone, a fluorine, an alkyd, an unsaturated polyester, a polyolefin, a wax or so may be used. Particularly, the silicone releasing agent is preferable since it can attain low releasing force. If the film used as the releasing film has weak surface tension by itself, and has low releasing force to the adhesive layer, such as the polyolefin film, then there is no need for the releasing treatment.

As the method of the releasing treatment, the releasing agent is coated using a gravure coater, a meyer-bar coater, an air knife coater, or a roll coater or so to said film without the solvent, or by solvent diluting or emulsifying. Then, the releasing agent is heated, or irradiated with the ultraviolet ray or the electron beam for curing, thereby the releasing layer is formed.

The thickness of the above releasing film is preferably 12 μm or thicker, more preferably 15 to 1000 μm, and particularly preferably 50 to 200 μm. When the releasing film is too thin, the size accuracy of the adhesive sheet itself becomes insufficient, against the stress accumulating during the steps of stacking each layer constituting the adhesive sheet and the step of winding the adhesive sheet. If the releasing layer is too thick, the whole thickness of the adhesive sheet becomes too thick, hence it becomes difficult to handle.

### (The Manufacturing of the Adhesive Sheet)

The adhesive sheet of the present invention is manufactured by coating a suitable thickness of the energy ray-curable polymer forming the intermediate layer on the substrate using the known coating apparatus, followed by drying; then on said intermediate layer, a suitable thickness of the adhesive is coated using the known coating apparatus, and dried to form the adhesive layer. As the coating apparatus forming the intermediate layer and the adhesive layer, a roll coater, a knife coater, a roll knife coater, a fountain die coater, a slot die coater, or a reverse die coater or so may be mentioned. It is preferable to superimpose the releasing film on the adhesive layer in order to protect the adhesive layer. Alternatively, it may be manufactured by placing the adhesive layer on the releasing film, and coating said intermediate layer on the adhesive layer, followed by transferring to the substrate. Besides the above mentioned methods, it may be manufactured by placing the intermediate layer, and the adhesive layer on the releasing film separately, then transferring these sequentially on the substrate.

The thickness of the intermediate layer and the adhesive layer are selected depending on the height and shape of the bumps, and pitches of the space between the bumps or so of the adherend on which the adhesive sheet is stuck. Generally, the thickness of the intermediate layer and the adhesive layer are preferably selected to be 110% or more of the height of the bumps and more preferably 130 to 500%. By selecting the thickness of the intermediate layer and the adhesive layer as such, the adhesive sheet follows the roughness of the circuit surface and can resolve the roughness thereof.

### (The Characteristics of the Adhesive Sheet)

The intermediate layer of the adhesive sheet of the present invention is formed by the energy ray-curable polymer bound with the polymerizable group and the radical-generating group; hence there is no need to further add the low-molecular weight compounds such as the photopolymerization initiator or the energy ray-polymerizable compound or so to the intermediate layer. Thus, the amount of the low-molecular weight compounds included in the intermediate layer is significantly reduced. Therefore, the compositional change along with the evaporation of the low-molecular weight compounds when forming the intermediate layer does not occur. Also, when storing the adhesive sheet, since the low-molecular weight compounds does not move to the adhesive layer, the long term storage stability of the adhesive sheet improves.

As the adherend to the adhesive sheet of the present invention, the semiconductor wafer formed with the circuit having the bumps on the surface thereof is particularly suitable. Also as the back side grinding thereof, the back side grinding of the semiconductor wafer formed with the circuit having the bumps on the surface is particularly suitable. Here, the heights of the bumps are not particularly limited, and according to the method of the present invention, it can be applied to the processing of the semiconductor wafer formed with the circuit with the bumps having the height of 40 μm or higher, further 50 to 400 μm, and particularly 70 to 300 μm.

### (The Processing Method of the Semiconductor Wafer)

The adhesive sheet of the present invention can be used for processing the semiconductor wafer as described in the following.

### (The Wafer Back Side Grinding Method)

During the back side grinding of the wafer, the wafer processing adhesive sheet is stuck to the circuit face of the semiconductor wafer formed with the circuit on the surface to protect the circuit surface while the back side grinding of the wafer and to have a predetermined thickness of the wafer.

The semiconductor wafer can be a silicon wafer, or a compound semiconductor wafer such as gallium arsenide. The formation of the circuit on the wafer surface can be performed by conventionally widely used various methods such as an etching method and a lift off method or so. The desirable circuit is formed during the circuit forming step of the semiconductor wafer. The thickness of such wafer at before the grinding is not particularly limited, however it is usually 500 to 1000 μm or so.

When using the adhesive sheet of the present invention, after sticking the adherend, the energy ray is applied to the adhesive sheet before the back side grinding step to cure the intermediate layer. The adhesive layer and the intermediate layer have sufficient elastic modulus to follow the roughness of the bumps at before applying the energy ray. Therefore, it can be embedded to the wafer surface formed with the bumps, thus can resolve the roughness, and maintain the wafer in a flat status. Further, by applying the energy ray to polymerize and cure, the wafer can be fixed while at said flat status. Therefore, even when the strong shear force is applied to the wafer during the back side grinding of the wafer, the vibration and the positional shift of the wafer can be prevented; thereby the wafer can be held flat and can be ground to be extremely thin. When the adhesive layer is energy ray-curable, it is preferable that the intermediate layer and the adhesive layer are cured at the same time.

As described in the above, the adhesive sheet has a property that increases the storage elastic modulus of the intermediate layer by the energy ray irradiation.

As for the energy ray, specifically, an ultraviolet ray, an electron beam or so may be used. Also, the irradiation amount varies depending on the type of the energy ray, and for example, when using the ultraviolet ray, the ultraviolet ray intensity is preferably 50 to 300 mW/cm² or so, and the ultraviolet ray irradiation amount is preferably 100 to 1200 mJ/cm² or so.

The back side grinding is performed by known methods using the grinder and the vacuum table or so for fixing the wafer while the adhesive sheet is stuck. After the back side grinding step, the treatment to remove the fractured layer due to the grinding may be performed. The thickness of the semiconductor wafer after the back side grinding step is not particularly limited; however it is preferably 10 to 300 μm and particularly 25 to 200 μm or so.

After the back side grinding step, the adhesive sheet is peeled from the circuit surface. According to the adhesive sheet of the present invention, the adhesive layer and the intermediate layer absorbs the roughness of the circuit surface, and securely holds the wafer during the back side grinding of the wafer, further it can prevent the leakage of the grinding water into the circuit surface. Also, according to the adhesive sheet of the present invention, the content of the low-molecular weight compounds included in the intermediate layer can be significantly reduced, hence the low-molecular weight compounds does not flow out due to the grinding water. Also, the change in the adhesive strength of the adhesive layer and the wafer contamination caused by the move of the low-molecular weight compounds can be prevented.

### (The Wafer Back Side Processing Method)

Also, followed by said back side grinding step, various processing are performed to the back side of the wafer.

For example, in order to further form the circuit pattern to the back side of the wafer, the treatment involving the heating such as an etching treatment or so may be performed. Also, the die bond film may be heat pressed to the back side of the wafer. During these steps, the circuit pattern can also be protected by sticking the adhesive sheet of the present invention; and, it will be exposed to a high temperature condition. However, since the low-molecular weight compounds is not substantially included in the intermediate layer of the adhesive sheet of the present invention, the evaporation of the low-molecular weight compounds by heating generation and heating during the processing can be suppressed.

### (The Wafer Dicing Method)

The adhesive sheet of the present invention can be used as a dicing sheet.

When using as the dicing sheet, it is suitable in case the adhesive sheet of the present invention is stuck on the circuit surface of the wafer to cut the wafer. The sticking of the dicing sheet is generally performed by the apparatus called as a mounter, however it is not limited thereto.

The means for cutting the semiconductor wafer is not particularly limited. As for an example, the method of forming chips from a wafer by known methods such as a method using a rotating round blade of dicer or so after fixing the peripheral portion of the dicing sheet by the ring flame when cutting the wafer may be mentioned. Alternatively, it may be a dicing method using a laser light. According to the adhesive sheet of the present invention, the content of the low-molecular weight compounds included in the intermediate layer can be significantly reduced; hence the low-molecular weight compounds does not flow out due to the cutting water.

### (The Dicing Method According to the DBG Method)

Furthermore, the adhesive sheet of the present invention is particularly preferably used to form the chips from the wafer having a high bumps using the DBG method. Specifically, it is preferably used for the processing method of the semiconductor wafer including the forming of grooves having a depth of cut shallower than a wafer thickness from the surface of the semiconductor wafer formed with the circuit having bumps, sticking the adhesive sheet as for the surface protection sheet, thinning of the wafer thickness by the back side grinding of said semiconductor wafer, and dividing into individual chips, followed by picking up said chips. Further specifically, it is used for the processing method of the semiconductor wafer comprising the following steps.

The first step: The grooves having the predetermined depth from the wafer surface is formed along the cutting position of the wafer dividing the plurality of the chips.

The second step: The adhesive sheet of the present invention is stuck so that it covers the whole surface of said wafer, then the energy ray is applied to the intermediate layer for curing. At this point, if the adhesive layer is energy ray-curable, it is preferable that the adhesive layer is cured at the same time with curing the intermediate layer.

The third step: Then the back side of the wafer is ground till the bottom portion of said grooves are removed and it has the predetermined thickness to divide into each individual chips. When grinding, the grinding is performed by supplying water (the grinding water) to the grinding surface in order to remove the grinding dusts and grinding heat. By using the adhesive sheet of the present invention at this point, since high sealing property can be obtained between the chip and the adhesive layer, the grinding water does not leak into the circuit surface; hence the contamination of the chip can be prevented.

Then, the chips are picked up by the predetermined method. Also, the pick up of the chips can be performed by transferring the chip which is aligned in the wafer form to the other adhesive sheet, before the pick up of the chips.

When using the adhesive sheet of the present invention to the manufacturing step of the semiconductor device by such DBG method, a film having relatively high rigidity such as a polyethylene telephthalate film or a polyethylene naphthalate film or so is preferably used as the substrate; in order to prevent the chip crack when forming the chip by the back side grinding and to prevent the calf width of the divided chips from shrinking. However, if the substrate has rigidity, it becomes difficult to follow the wafer roughness by elasticity of the substrate; hence the role of the intermediate layer becomes further important.

### EXAMPLE

Hereinafter the present invention will be described based on the examples; however the present invention is not limited thereto.

### Example 1

### Synthesis of the Radical-Generating Group Containing Monomer

The radical-generating group containing monomer was obtained by mixing and reacting, 1-[4-(2-hydroxyethoxy)-phenyl]-2-hydroxy-2-methyl-1-propan-1-one (made by Ciba speciality chemical Inc., product name “IRGACURE 2959”) and methacryloyloxyethyl isocyanate (MOI) at the same molar ratio.

### (Formation of the Radical-Generating Group Containing Polymer)

The acrylic radical-generating group containing polymer was synthesized by a solution polymerization in ethyl acetate solution using; 57 parts by weight of butyl acrylate (BA), 10 parts by weight of methylmethacrylate (MMA), 28 parts by weight of 2-hydroxyethylacrylate (HEA) as the functional group containing monomer, and 5 parts by weight of the radical-generating group containing polymerizable monomer (PI-MOI) formed in the above. 2,2-′azobisisobutylonitrile was used as the polymerization initiator, and 2,4-diphenyl-4-methyl-1-pentene was used as the chain transfer agent. (Hereinafter, if not particularly mentioned, the above mentioned polymerization initiator and the chain transfer agent during the synthesis of the radical-generating group containing polymerizable copolymer are used).

### (Formation of the Energy Ray-Curable Polymer)

100 parts by weight in terms of the solid portion, of this acrylic radical-generating group containing polymer and 30 parts by weight of methacryloyloxyethyl isocyanate (80 equivalent amounts with respect to 100 equivalent amounts of the hydroxyl group as a functional group of the acrylic radical-generating group containing polymer) were reacted and obtained ethyl acetate solution (30% solution) of the acrylic energy ray-curable polymer having weight average molecular weight of 630,000 including the bonding polymerization group and radical-generating group.

### (Formation of the Intermediate Layer Composition)

With respect to 100 parts by weight of this acrylic energy ray-curable polymer, 0.188 parts by weight (solid portion) of the polyvalent isocyanate compound (made by Nippon Polyuthance Co., product name “Coronate L”) were mixed to obtain the acrylic intermediate layer composition.

### (Formation of the Adhesive Layer Composition)

85 parts by weight of butyl acrylate, 10 parts by weight of methyl methacrylate, 5 parts by weight of 2-hydroxyethylacrylate were solution polymerized in ethyl acetate solution to synthesize acrylic copolymer having weight average molecular weight of 500,000. 2,2-′azobisisobutylonitrile was used as the polymerization initiator, and 2,4-diphenyl-4-methyl-1-pentene was used as the chain transfer agent. With respect to 100 parts by weight of this acrylic copolymer, 0.75 parts by weight (solid portion) of the polyvalent isocyanate compound (made by Nippon Polyurethance Co., product name “Coronate L”) were mixed to obtain the acrylic adhesive composition.

### (Formation of the Adhesive Sheet)

The above mentioned acrylic intermediate layer composition was coated, so that the thickness of the coat is 200 μm after the drying, by using the roll knife coater to the release treated surface of the polyethylene telephtalate film (thickness of 38 μm) which is silicone release treated as the releasing film. Next, after drying at 120° C. for 2 minutes, then polyethylene film having thickness of 110 μm as the substrate was stacked to the obtained intermediate layer to obtain the film in which the intermediate layer and the substrate are stacked.

Aside from this, the above mentioned acrylic adhesive composition was coated, so that the thickness of the coat is 40 μm after the drying, by using the roll knife coater to the release treated surface of the polyethylene telephtalate film (thickness of 38 μm) which is silicone release treated as the releasing film. Next, after drying at 100° C. for 1 minute, the releasing film (the releasing film having different releasing force than that of above mentioned) was stacked on to the obtained adhesive layer and formed the adhesive layer sheet sandwiched between two releasing films.

The releasing film having a weaker releasing force, among the formed two releasing film sandwiching the adhesive layer sheet was released. Also, the releasing film of the film in which the above obtained intermediate layer and the substrate are stacked, was released. The intermediate layer and the adhesive layer were stuck to each other to obtain the adhesive sheet.

In order to stabilize the adhesive strength, it was left under the atmosphere of 23° C. 50% RH for 7 days, and then the following physical property and the ability were evaluated.

### (The Surface Contamination Property)

The surface contamination property when using the above mentioned adhesive sheet as the surface protection sheet during the back side grinding of the semiconductor wafer was evaluated as the following.

The above mentioned adhesive sheet was stuck to the patterned surface of dummy wafer (thickness: 725 μm, surface status: comprises the circuit pattern having 20 μm step difference at maximum), by using the tape laminator (made by LINTEC Corporation, product name “RAD-3510F/12”). Next, the ultra violet ray irradiation was performed (irradiation condition: intensity 240 mW/cm², amount of light 600 mJ/cm²) by using the ultra violet irradiation apparatus (made by LINTEC Corporation, product name “RAD-2000 m/12”) from the substrate of the adhesive sheet. Then, by using the wafer back side grinding apparatus (made by Disco Corporation, product name “DGP-8760”), the wafer thickness was ground till it becomes 100 μm thick. Next, by using the tape mounter (made by LINTEC Corporation, product name “RAD-2700F/12”), the dicing tape (made by LINTEC Corporation, product name “D-185”) was stuck to the grinding surface, then said adhesive sheet was released from the circuit surface.

Next, the circuit surface of the dummy wafer was observed using the digital microscope (made by KEYENCE CORPORATION, product name “Digital microscope VHX-200”) at 2000 magnification. When the adhesive residual was not found, the surface contamination property was evaluated “good”, and when the residual was found, the surface contamination property was evaluated “bad”.

### (The Grinding Suitability of the High Bump Semiconductor Wafer)

The grinding suitability of the high bump semiconductor when using the above mentioned adhesive sheet as the surface protection sheet during the back side grinding of the semiconductor wafer was evaluated as following.

The above mentioned adhesive sheet was stuck to patterned surface of the dummy wafer (thickness: 725 μm, surface status: comprise the circuit pattern having 150 μm step difference at maximum), by using the tape laminator (made by LINTEC Corporation, product name “RAD-3510F/12”). Next, the ultra violet ray irradiation was performed (irradiation condition: intensity 240 mW/cm², amount of right 600 mJ/cm²) by using the ultra violet irradiation apparatus (made by LINTEC Corporation, product name “RAD-2000 m/12”) from the substrate of the adhesive sheet. Then, by using the wafer back side grinding apparatus (made by Disco Corporation, product name “DGP-8760”), the wafer thickness was ground till it becomes 100 μm thick. When the semiconductor wafer did not break during the back side grinding, then it was evaluated as “good”, and when the semiconductor wafer broke, then it was evaluated as “bad”.

(The Weight Reduction Rate (The Volatile Gas Amount) after Heating)

The weight reduction rate after heating was evaluated by measuring the weight reduction using the differential thermal•thermalgravity simultaneous instrument (made by SHIMADZU CORPORATION, product name “DTG-60”). A piece of the above mentioned adhesive sheet (0.01 g; releasing film was removed) was heated up to 120° C. at 10° C./min, then maintained at 120° C. for 60 minutes, and determined the weight reduction rate of before and after the heating.

### Example 2

The acrylic radical-generating group containing polymer was synthesized by solution polymerizing in ethyl acetate solution using, 68.2 parts by weight of butyl acrylate, 10 parts by weight of methyl methacrylate, 16.8 parts by weight of 2-hydroxyethylacrylate, and 5 parts by weight of the radical-generating group containing monomer prepared in the example 1. 100 parts by weight in terms of the solid portion of this radical-generating group containing polymer and 18.7 parts by weight methacryloyloxyethyl isocyanate (83.3 equivalent amount with respect to 100 equivalent amount hydroxyl group as a functional group of the acrylic radical-generating group containing polymer) were reacted, and obtained ethyl acetate solution (30% solution) of the energy ray-curable polymer having weight average molecular weight of 680,000 including the bonding polymerization group and radical-generating group.

With respect to 100 parts by weight of the energy ray-curable polymer, 0.188 parts by weight (solid portion) of the polyvalent isocyanate compound (made by Nippon Polyurethance Co., product name “Coronate L”) were mixed to obtain the acrylic intermediate layer composition.

The same procedures were performed as the example 1 except for forming the intermediate layer by using the above mentioned intermediate layer composition. The results are shown in Table 1.

### Example 3

The acrylic radical-generating group containing polymer was synthesized by solution polymerizing in ethyl acetate solution using, 72.2 parts by weight of butyl acrylate, 10 parts by weight of methyl methacrylate, 16.8 parts by weight of 2-hydroxyethylacrylate, and 1 parts by weight of the radical-generating group containing monomer prepared in the example 1. 100 parts by weight in terms of the solid portion of this radical-generating group containing polymer and 18.7 parts by weight methacryloyloxyethyl isocyanate (83.3 equivalent amount with respect to 100 equivalent amount hydroxyl group as a functional group of the acrylic radical-generating group containing polymer) were reacted, and obtained ethyl acetate solution (30% solution) of the energy ray-curable polymer having weight average molecular weight of 680,000 including the bonding of polymerization group and radical-generating group.

With respect to 100 parts by weight of the energy ray-curable polymer, 0.188 parts by weight (solid portion) of the polyvalent isocyanate compound (made by Nippon Polyurethance Co., product name “Coronate L”) were mixed to obtain the acrylic intermediate layer composition.

The same procedures were performed as the example 1 except for forming the intermediate layer by using the above mentioned intermediate layer composition. The results are shown in Table 1.

### Comparative Example 1

The acrylic copolymer was synthesized by solution polymerizing in ethyl acetate solution using, 62 parts by weight of butyl acrylate, 10 parts by weight of methyl methacrylate, and 28 parts by weight of 2-hydroxyethylacrylate. 100 parts by weight in terms of the solid portion, of this acrylic copolymer and 30 parts by weight of methacryloyloxyethyl isocyanate (80 equivalent amount with respect to 100 equivalent amount hydroxyl group as a functional group of the acrylic radical-generating group containing polymer) were reacted, and obtained ethyl acetate solution (30% solution) of the acrylic copolymer having weight average molecular weight of 600,000 including the bonding polymerizable group via an alkylene oxide group. The obtained acrylic copolymer comprises the energy ray-polymerizable group, however it does not comprise radical-generating group.

With respect to 100 parts by weight of the energy ray-curable polymer, 0.188 parts by weight (solid portion) of the polyvalent isocyanate compound (made by Nippon Polyurethance Co., product name “Coronate L”), and 3.3 parts by weight (solid portion) of the photopolymerization initiator (made by Ciba speciality chemical Inc., product name “IRGACURE 184”) were mixed and obtained the acrylic intermediate layer composition.

The same procedures were performed as the example 1 except for forming the intermediate layer by using the above mentioned intermediate layer composition. The results are shown in Table 1.

### Comparative Example 2

90 parts by weight of butyl acrylate and 10 parts by weight of acrylic acid were solution polymerized in the ethyl acetate solution, and obtained ethyl acetate solution (30% solution) of the acrylic copolymer having weight average molecular weight of 600,000. The obtained acrylic copolymer did not comprise the energy ray-polymerizable group and the radical-generating group.

With respect to 100 parts by weight of the energy ray-curable polymer, 0.75 parts by weight (solid portion) of polyvalent isocyanate compound as a crosslinker (made by Nippon Polyurethance Co., product name “Coronate L”), 15 parts by weight (solid portion 70%) of an ultraviolet ray-curable resin (made by Nippon Synthetic ChemicaL Inductries Co., product name “SHIKOH UV-3210EA”) and 3.3 parts by weight (solid portion) of the photopolymerization initiator (made by Ciba speciality chemical Inc., product name “IRGACURE 184”) were mixed and obtained the acrylic intermediate layer composition.

The same procedures were performed as the example 1 except for forming the intermediate layer by using the above mentioned intermediate layer composition. The results are shown in Table 1.

### Comparative Example 3

85 parts by weight of butyl acrylate, and 15 parts by weight of 2-hydroxyethylacrylate were solution polymerized in an ethyl acetate solution, and synthesized the acrylic copolymer having weight average molecular weight 600,000. 100 parts by weight in terms of the solid portion of this acrylic copolymer and 16.1 parts by weight methacryloyloxyethyl isocyanate (80 equivalent amounts with respect to 100 equivalent amounts of hydroxyl group as a functional group of the acrylic polymer) were reacted, and obtained ethyl acetate solution (30% solution) of the acrylic copolymer including the bonding polymerizable group via an alkylene oxide group. The obtained acrylic copolymer comprises the energy ray-curable group, however it does not comprise the radical-generating group.

With respect to 100 parts by weight of the energy ray-curable polymer, 0.188 parts by weight (solid portion) of the polyvalent isocyanate compound as a crosslinker (made by Nippon Polyurethance Co., product name “Coronate L”), and 3.3 parts by weight (solid portion) of the photopolymerization initiator (made by Ciba speciality chemical Inc., product name “IRGACURE 184”) were mixed and obtained the acrylic intermediate layer composition.

The same procedures were performed as the example 1 except for forming the intermediate layer by using the above mentioned intermediate layer composition. The results are shown in Table 1.

TABLE 1

| | | | | | | Example 1 | Example 2 | Example 3 |
|---|---|---|---|---|---|---|---|---|
| Constitution | Intermediate | Energy ray- | Radical- | Radical-generating group | PI-MOI | 5 | 5 | 1 |
| | layer | polymerizable | generating | containing monomer (a1-1) | | | | |
| | | copolymer (A) | group | Functional group containing | HEA | 28 | 16.8 | 16.8 |
| | | | containing | monomer (a1-2) | AA | — | — | — |
| | | | copolymer | Other monomer (a1-3) | BA | 57 | 68.2 | 72.2 |
| | | | (a1) | | MMA | 10 | 10 | 10 |
| | | | Energy ray-polymerizable group | | MOI | 30 | 18.7 | 18.7 |
| | | | containing compound (a2) | | | | | |
| | | | Used amount (equivalent amount) | | | 80 | 83.3 | 83.3 |
| | | | with respect to OH group 100 | | | | | |
| | | | equivalent amount within (a1-2) | | | | | |
| | | Other additives (B) | | | Coronate L | 0.188 | 0.188 | 0.188 |
| | | Ultraviolet ray-curable resin | | | Shikoh | — | — | — |
| | | | | | UV-3210 | | | |
| | | | | | EA | | | |
| | | Photoinitiator | | | IRGACURE | — | — | — |
| | | | | | 184 | | | |
| | Adhesive | Acrylic adhesive | | | BA | 85 | 85 | 85 |
| | | | | | MMA | 10 | 10 | 10 |
| | | | | | HEA | 5 | 5 | 5 |
| | | Crosslinker | | | Coronate L | 0.75 | 0.75 | 0.75 |
| Evaluation | Surface contamination property | | | | | Good | Good | Good |
| items | Grinding suitability of the high bump semiconductor wafer | | | | | Good | Good | Good |
| | Weight reduction rate after heating (Volatile gas amount) | | | | | −2.2 | −2.04 | −2.12 |
| | | | | | | Comp. | Comp. | Comp. |
| | | | | | | example 1 | example 2 | example 3 |
| Constitution | Intermediate | Energy ray- | Radical- | Radical-generating group | PI-MOI | — | — | — |
| | layer | polymerizable | generating | containing monomer (a1-1) | | | | |
| | | copolymer (A) | group | Functional group containing | HEA | 28 | — | 15 |
| | | | containing | monomer (a1-2) | AA | — | 10 | — |
| | | | copolymer | Other monomer (a1-3) | BA | 62 | 90 | 85 |
| | | | (a1) | | MMA | 10 | — | — |

| | | | | |
|---|---|---|---|---|
| Energy ray-polymerizable group | MOI | 30 | — | 16.1 |
| containing compound (a2) | | | | |
| Used amount (equivalent amount) | | 80 | | 80 |
| with respect to OH group 100 | | | | |
| equivalent amount within (a1-2) | | | | |

| | | | | | |
|---|---|---|---|---|---|
| | Other additives (B) | Coronate L | 0.188 | 0.75 | 0.188 |
| | Ultraviolet ray-curable resin | Shikoh | — | 15 | — |
| | | UV-3210 | | | |
| | | EA | | | |
| | Photoinitiator | IRGACURE | 3.3 | 3.3 | 3.3 |
| | | 184 | | | |
| Adhesive | Acrylic adhesive | BA | 85 | 85 | 85 |
| | | MMA | 10 | 10 | 10 |
| | | HEA | 5 | 5 | 5 |
| | Crosslinker | Coronate L | 0.75 | 0.75 | 0.75 |

| | | | | |
|---|---|---|---|---|
| Evaluation | Surface contamination property | Bad | Bad | Bad |
| items | Grinding suitability of the high bump semiconductor wafer | Generated | Generated | Generated |
| | | crakcs | crakcs | crakcs |
| | Weight reduction rate after heating (Volatile gas amount) | −5.86 | −6.5 | −5.65 |

As obvious from the result shown in the Table 1, the surface contamination property, the grinding suitability of the high bump semiconductor wafer, and the volatile gas amount of the adhesive sheet of the present invention obtained by the examples were better compared to the adhesive sheet obtained by the comparative examples.

### INDUSTRIAL APPLICABILITY

According to the present invention, in the adhesive sheet having a multilayered adhesive layer, the low-molecular weight compounds included in the intermediate layer is significantly reduced; hence various problems such as compositional changes due to the low-molecular weight compounds moving and evaporating, and volatile gas generation or so. The examples show the specific example of back side grinding of the semiconductor wafer, however the present invention is not limited to the back side grinding and it is effective in the wafer dicing or DBG method, or any purpose other than semiconductor process having above mentioned problems.

1. An adhesive sheet comprising a substrate, an intermediate layer formed thereon, and an adhesive layer formed on said intermediate layer, wherein, said intermediate layer includes an energy ray-curable polymer in which an energy ray-polymerizable group and a radical-generating group initiating a polymerization under excitation by an energy ray are bound at a main chain or side chain.

2. The adhesive sheet as set forth in claim 1, wherein said radical-generating group includes phenyl carbonyl group which comprises a substituent group at an aromatic ring.

3. The adhesive sheet as set forth in claim 1, wherein said radical-generating group is derived from a monomer obtained by adding a compound containing a polymerizable double bond to a hydroxyl group of a photopolymerization initiator having the hydroxyl group.

4. The adhesive sheet as set forth in claim 1, wherein said energy ray-curable polymer has a weight average molecular weight of 300000 to 1600000.

5. The adhesive sheet as set forth in claim 1 used for processing of a semiconductor wafer.

6. A processing method of a semiconductor wafer, wherein a circuit surface of the semiconductor wafer formed with a circuit on the surface is stuck to the adhesive layer of the adhesive sheet as set forth in claim 1, and performs a back side processing of said semiconductor wafer.

7. The processing method of the semiconductor wafer as set forth in claim 6, wherein said back side processing of said semiconductor wafer is a back side grinding.

8. A processing method of the semiconductor wafer, wherein a circuit surface of the semiconductor wafer formed with a circuit on the surface is stuck to the adhesive layer of the adhesive sheet as set forth in claim 1, and performing a dicing of said semiconductor wafer.

9. The processing method of the semiconductor wafer as set forth in claim 6, wherein the circuit surface of the semiconductor wafer formed with the circuit having bumps on the surface is stuck to the adhesive layer of the adhesive sheet, and performs a processing of said semiconductor wafer.

10. A processing method of the semiconductor wafer comprising:
forming grooves having a depth of cut shallower than a wafer thickness from the surface of the semiconductor wafer formed with the circuit having bumps,
sticking the adhesive sheet as set forth in claim 1 on to the circuit surface,
thinning the wafer thickness by back side grinding of said semiconductor wafer, and
dividing into individual chips, followed by picking up said chips.
